(19) United States
(12) Patent Application Publication
(10) Pub. No.: US 2024/0322069 A1
(43) Pub. Date: Sep. 26, 2024

(54) OPTOELECTRONIC SEMICONDUCTOR DEVICE, ARRAY OF OPTOELECTRONIC SEMICONDUCTOR DEVICES AND METHOD FOR MANUFACTURING AN OPTOELECTRONIC SEMICONDUCTOR DEVICE

(71) Applicant: ams-OSRAM International GmbH, Regensburg (DE)

(72) Inventor: Tansen Varghese, Regensburg (DE)

(21) Appl. No.: 18/572,699

(22) PCT Filed: Jun. 29, 2022
(86) PCT No.: PCT/EP2022/067933

§ 371 Date: Dec. 20, 2023

(30) Foreign Application Priority Data
Jul. 2, 2021 (DE) 10 2021 117 123.7

(51) Int. Cl. H01L 33/00; H01L 27/15; H01L 33/24; H01L 33/38; H01L 33/44

(52) U.S. Cl. CPC H01L 33/0066; H01L 27/156; H01L 33/24; H01L 33/385; H01L 33/44; H01L 2933/0016; H01L 2933/0025

(57) ABSTRACT

In an embodiment a method for manufacturing an optoelectronic semiconductor device includes forming a semiconductor layer stack comprising an active zone for generating or receiving electromagnetic radiation, forming a hard mask layer over the semiconductor layer stack, patterning the hard mask layer to form a hard mask having a width d measured in a first lateral direction, patterning the semiconductor layer stack to form a mesa having a width w measured in the first lateral direction with d>w, wherein the hard mask protrudes from the mesa at a first lateral end and at a second lateral end of the mesa, and wherein the first lateral end and the second lateral end are arranged at opposing sides of the mesa along the first lateral direction, forming a cover layer over sidewalls of the mesa and etching the cover layer using the hard mask as an etching mask to form a separating groove.

### CROSS-REFERENCE TO RELATED APPLICATIONS

This patent application is a national phase filing under section 371 of PCT/EP2022/067933, filed Jun. 29, 2022, which claims the priority of German patent application 10 2021 117 123.7, filed Jul. 2, 2021, each of which is incorporated herein by reference in its entirety.

### TECHNICAL FIELD

The disclosure relates to an optoelectronic semiconductor device, an array of optoelectronic semiconductor devices and a method for manufacturing an optoelectronic semiconductor device.

### BACKGROUND

An optoelectronic semiconductor device usually comprises differently doped semiconductor layers as well as an active zone. For example, when the optoelectronic semiconductor device is implemented as a light emitting diode (LED), electrons and holes may recombine with each other within the active zone, for example, when a corresponding voltage is applied to the optoelectronic semiconductor device. When electrons and holes recombine with each other, electromagnetic radiation is generated. Mesa etching is usually performed during the manufacture of micro LEDs in order to optically and electrically isolate the individual devices, or to isolate the pixels in an array. Mesa etching is also performed when manufacturing photodetectors or other radiation receiving devices in order to reduce the capacitance and therefore increase the speed.

### SUMMARY

Embodiments provide an improved optoelectronic semiconductor device and an improved method for manufacturing an optoelectronic semiconductor device.

An optoelectronic semiconductor device comprises a semiconductor layer stack comprising an active zone for generating or receiving electromagnetic radiation, the semiconductor layer stack being patterned to form a mesa having a width w measured in a first lateral direction. The optoelectronic semiconductor device further comprises a hard mask arranged over the semiconductor layer stack and having a width d measured in the first lateral direction, with d>w, the hard mask protruding from the mesa at a first lateral end and at a second lateral end of the mesa, the first lateral end and the second lateral end being arranged at opposing sides of the mesa along the first lateral direction, wherein the hard mask comprises a conductive layer directly adjacent to a semiconductor layer of the semiconductor layer stack. The optoelectronic semiconductor device additionally comprises a cover layer arranged over sidewalls of the mesa, the cover layer comprising a semiconductor material.

Generally, within the present disclosure, the mesa may have the shape of a square, a circle, a square having rounded corners, a hexagon or a hexagon having rounded corners. For example, the mesa may have the width d measured in a second lateral direction that may intersect or may be perpendicular to the first lateral direction.

For example, according to all embodiments, the hard mask may protrude from the mesa at opposing lateral ends of the mesa, e.g. along the second lateral direction. According to embodiments, the hard mask may protrude at any side of the mesa.

According to all embodiments, the conductive layer may at least extend from one side of the mesa to the other side of the mesa. For example, the conductive layer may protrude at opposing lateral ends of the mesa, e.g. along the second lateral direction. According to embodiments, the conductive layer may protrude at any side of the mesa.

The hard mask may further comprise a dielectric layer.

For example, a width of the cover layer may be equal to at least a difference between d and w, the width being measured in the first lateral direction.

A band gap of a material of the cover layer may be larger than the band gap of the active zone, e.g. of any layer or quantum well structure constituting the active zone. For example, the band gap of all materials of the cover layer may be larger than the band gap of any layer or quantum well structure constituting the active zone.

According to embodiments, the semiconductor layer stack comprises a first semiconductor layer of a first conductivity type and a second semiconductor layer of a second conductivity type and the active zone is arranged between the first semiconductor layer and the second semiconductor layer. The second semiconductor layer is directly adjacent to the conductive layer.

For example, the cover layer comprises a first sublayer of a first conductivity type and a second sublayer of a second conductivity type, the first sublayer being directly adjacent to the sidewalls of the mesa. For example, the band gap of the first sublayer and/or the second sublayer may be larger than the band gap of the active zone, e.g. of any layer or quantum well structure constituting the active zone.

In an array of optoelectronic semiconductor devices as defined above, adjacent optoelectronic semiconductor devices may be separated from each other by a separating groove in the cover layer, the separating groove extending between the hard masks of the adjacent optoelectronic semiconductor devices.

An array of optoelectronic semiconductor devices comprises a semiconductor layer stack comprising an active zone for generating or receiving electromagnetic radiation, the semiconductor layer stack being patterned to form a plurality of mesas having a width w measured in a first lateral direction. The array further comprises portions of a hard mask arranged over the semiconductor layer stack and having a width d measured in the first lateral direction, with d>w, the hard mask protruding from each of the mesas at a first lateral end and at a second lateral end of each of the mesas, the first lateral end and the second lateral end being arranged at opposing sides of the mesas along the first lateral direction. The array additionally comprises a cover layer arranged over sidewalls of each of the mesas, the cover layer comprising a semiconductor material and a plurality of separating grooves between adjacent optoelectronic semiconductor devices, the separating groove extending between the portions of the hard mask of adjacent optoelectronic semiconductor devices and being directly adjacent to the portions of the hard mask of the adjacent optoelectronic semiconductor devices.

A method of manufacturing an optoelectronic semiconductor device comprises forming a semiconductor layer stack comprising an active zone for generating or receiving electromagnetic radiation, forming a hard mask layer over the semiconductor layer stack, patterning the hard mask layer to form a hard mask having a width d measured in the first lateral direction, and patterning the semiconductor layer stack to form a mesa having a width w measured in a first lateral direction with d>w. The hard mask protrudes from the mesa at a first lateral end and at a second lateral end of the mesa, the first lateral end and the second lateral end being arranged at opposing sides of the mesa along the first lateral direction. The method further comprises forming a cover layer over sidewalls of the mesa, the cover layer comprising a semiconductor material and etching the semiconductor material of the cover layer using the hard mask as an etching mask to form a separating groove.

According to embodiments, patterning the semiconductor layer stack may comprise an anisotropic etching step followed by an isotropic etching step.

For example, the semiconductor layer stack may comprise a first semiconductor layer of a first conductivity type and a second semiconductor layer of a second conductivity type and the active zone is arranged between the first semiconductor layer and the second semiconductor layer, the second semiconductor layer being formed to be directly adjacent to the hard mask layer.

According to embodiments, forming the hard mask layer comprises forming a conductive layer directly adjacent to the second semiconductor layer of the semiconductor layer stack.

According to further embodiments, forming the hard mask layer comprises forming a dielectric layer directly adjacent to the second semiconductor layer of the semiconductor layer stack.

The method may further comprise removing the dielectric layer after forming the separating groove.

According to embodiments, the method further comprises forming a passivation layer after forming the separating groove, removing horizontal portions of the passivation layer to expose a surface of the mesas, and forming a conductive material to cover the surface of the mesas.

For example, due to forming the separating grooves a plurality of semiconductor devices are obtained.

According to further embodiments, a portion of the semiconductor layer stack is maintained when forming the separating grooves. In this case, adjacent optoelectronic semiconductor devices may be electrically connected by a portion of the semiconductor layer stack.

An optoelectronic apparatus according to embodiments comprises the optoelectronic semiconductor device or the array of optoelectronic semiconductor devices as explained above.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIGS. 1A to 1K illustrate methods of manufacturing an optoelectronic semiconductor device;

FIG. 1K shows a cross-sectional view of an example of an optoelectronic semiconductor device;

FIGS. 2A and 2B show an example of a workpiece when performing further processing steps;

FIGS. 3A to 3D illustrate a further processing method according to embodiments;

FIG. 3D shows a cross-sectional view of an optoelectronic semiconductor device according to further embodiments;

FIGS. 4A to 4G illustrate processing steps of a method according to further embodiments;

FIG. 5A shows a cross-sectional view of a workpiece during processing, according to a modification;

FIG. 5B shows a cross-sectional view of an optoelectronic semiconductor device according to further embodiments;

FIG. 6 summarizes a method according to embodiments; and

FIG. 7 shows an optoelectronic apparatus according to embodiments.

### DETAILED DESCRIPTION OF ILLUSTRATIVE EMBODIMENTS

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “over”, “on”, “above”, “leading”, “trailing” etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The terms “wafer” or “semiconductor substrate” used in the following description may include any semiconductor-based structure that has a semiconductor surface. Wafer and structure are to be understood to include doped and undoped semiconductors, epitaxial semiconductor layers, e.g. supported by a base semiconductor foundation, and other semiconductor structures. For example, a layer of a first semiconductor material may be grown on a growth substrate of a second semiconductor material. According to further embodiments, the growth substrate may be an insulating substrate such as a sapphire substrate. Depending on the purpose of use, the semiconductor may be based on a direct or an indirect semiconductor material. Examples of semiconductor materials particularly suitable for generation of electromagnetic radiation comprise nitride-compound semiconductors, by which e.g. ultraviolet or blue light or longer wavelength light may be generated, such as GaN, InGaN, AlN, AlGaN, AlGaInN, phosphide-compound semiconductors, by which e.g. green or longer wavelength light may be generated such as GaAsP, AlGaInP, GaP, AlGaP, as well as further semiconductor materials including AlGaAs, SiC, ZnSe, GaAs, ZnO, Ga2O3, diamond, hexagonal BN und combinations of these materials. Further examples of semiconductor materials may as well be silicon, silicon-germanium and germanium. The stoichiometric ratio of the compound semiconductor materials may vary. In the context of the present specification, the term “semiconductor” further encompasses organic semiconductor materials.

The term “vertical” as used in this specification intends to describe an orientation which is arranged perpendicular to the first surface of a substrate or semiconductor body.

The terms “lateral” and “horizontal” as used in this specification intends to describe an orientation parallel to a first surface of a substrate or semiconductor body. This can be for instance the surface of a wafer or a die.

As employed in this specification, the terms “coupled” and/or “electrically coupled” are not meant to mean that the elements must be directly coupled together—intervening elements may be provided between the “coupled” or “electrically coupled” elements. The term “electrically connected” intends to describe a low-ohmic electric connection between the elements electrically connected together.

The term “electrically connected” further comprises tunnelling contacts between connected elements.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Embodiments of the present application are explained while referring to an LED. As is to be clearly understood, the optoelectronic semiconductor device according to all embodiments may as well be implemented as a light receiving device, e.g. a photodetector.

For performing the method according to embodiments, a semiconductor layer stack 105 is epitaxially grown over an appropriate substrate 100. In particular, the substrate 100 may be a growth substrate for the specific semiconductor layers of the semiconductor layer stack 105. For example, the semiconductor layer stack 105 may comprise a first semiconductor layer 110 of a first conductivity type, e.g. n-type, an active zone 115 and a second semiconductor layer 120 of a second conductivity type, e.g. p-type. For example, the semiconductor layers of the semiconductor layer stack 105 may comprise a phosphide compound semiconductor. For example, materials may comprise AlnGamIn1-n-mP or InuGa1-uAsvP1-v or mixtures thereof, with 0≤n≤1, 0≤m≤1 and n+m≤1, 0≤u≤1, 0≤v≤1. As is to be clearly understood, any other semiconductor material may be employed.

In the context of the present specification, the term “active zone” refers to those layers of the optoelectronic device which are configured to generate the electromagnetic radiation emitted by the optoelectronic device. Specific examples comprise inter alia a pn junction, a double heterostructure, a single quantum well structure (SQW), a multiple quantum well (MQW) structure and/or a quantum cascade structure and any combination of these structures. According to further embodiments, the term “active zone” also refers to those layers of the optoelectronic device which absorb electromagnetic radiation.

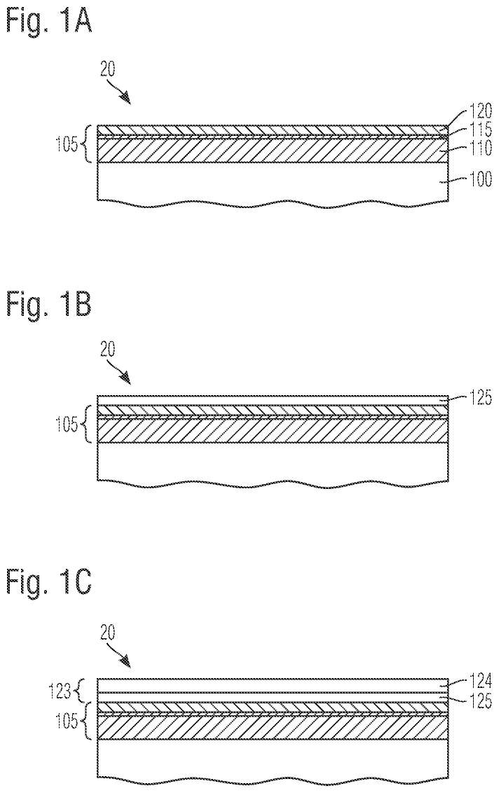

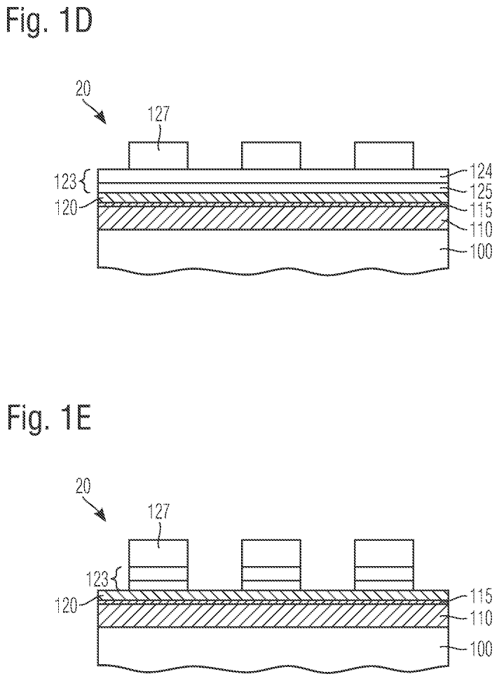

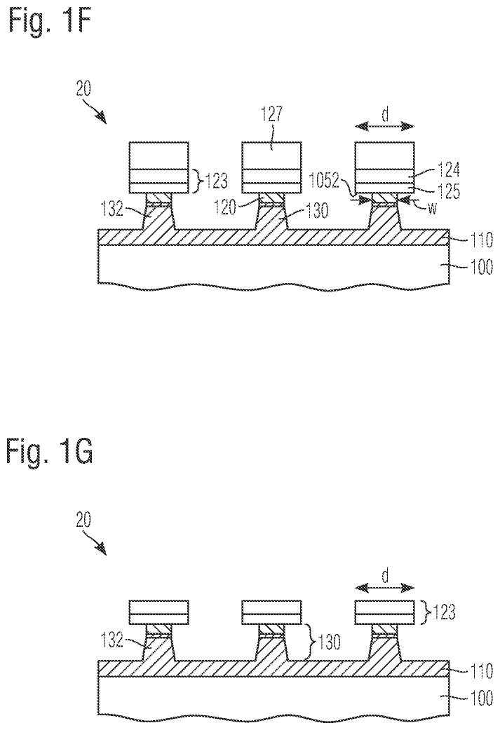

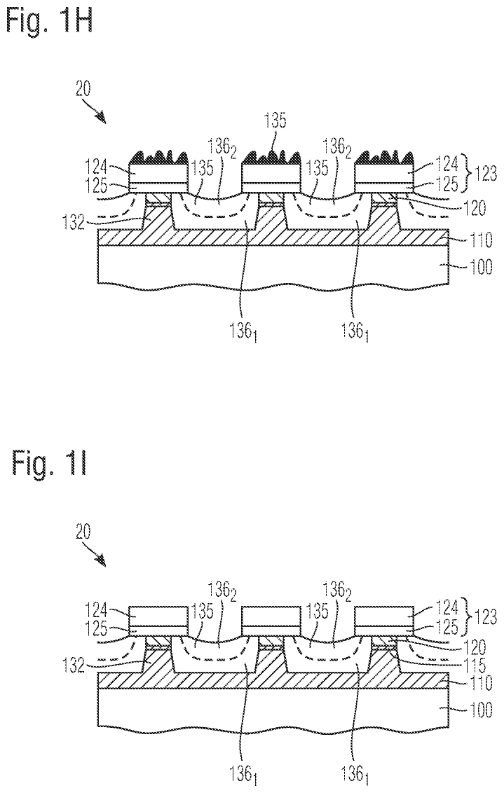

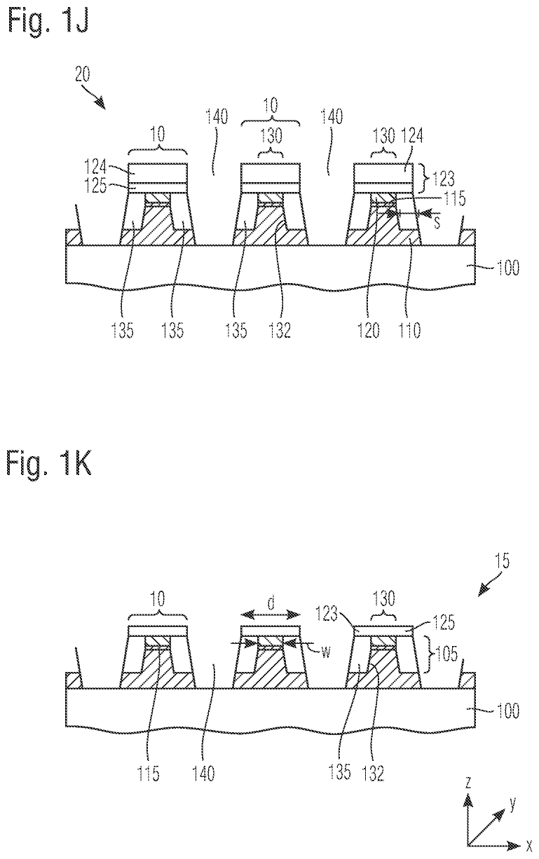

FIG. 1A shows an example of a resulting workpiece 20. Thereafter, as is illustrated in FIG. 1B, a conductive layer 125 may be formed over the semiconductor layer stack 105. For example, the conductive layer 125 may be a transparent conductive oxide layer, e.g. ITO (indium tin oxide). The conductive layer 125 may be formed in direct contact with the second semiconductor layer 120.

Then, as is shown in FIG. 1C, a dielectric layer 124 may be formed over the conductive layer 125. The dielectric layer 124 may, for example comprise silicon oxide or silicon nitride. The material of the dielectric layer 124 may be chosen so that the dielectric layer will not be etched while etching the underlying layers. Further, the material of the dielectric layer 124 may be chosen so that the dielectric layer 124 may be etched selectively with respect to the passivation layer which is to be formed in a subsequent step. The dielectric layer 124 may as well comprise several sublayers. The dielectric layer 124 and the conductive layer 125 form part of a hard mask layer 123. According to embodiments, the conductive layer 125 may as well be omitted.

In the next step as illustrated in FIG. 1D, a photoresist layer 127 is formed over the hard mask layer 123. The photoresist layer 127 is patterned e.g. using a photolithographic method. For example, the photoresist layer 127 may be patterned to squares. Using the patterned photoresist material 127 as an etching mask, the hard mask layer 123 is patterned. In particular, the portions of the dielectric layer 124 and the conductive layer 125 which are not covered by the photoresist material are etched.

FIG. 1E shows an example of a resulting workpiece 20. As is shown in FIG. 1E, portions of the second semiconductor layer 120 are covered by the hard mask 123 and the photoresist material 127. Further portions of the second semiconductor layer 120 are not covered by a hard mask 123 and, thus, are exposed.

In a next step, an etching process for etching the semiconductor layer stack 105 is performed. In particular, this etching comprises an anisotropic etching step in which an etching rate in a vertical direction is larger than in a horizontal direction. For example, this etching process may comprise a dry or plasma etching process. This etching is performed so as to completely etch the second semiconductor layer 120, the active zone 115 and portion of the first semiconductor layer 110. Further, an isotropic etching process is performed. For example, this etching process may comprise a wet etching step. Due to this etching step, a portion of the hard mask 123 facing the substrate 100 is exposed. For example, when the semiconductor layers of the semiconductor layer stack comprise layers of the (In)Ga(Al)P material system, the etchant may contain HCl For example, this etching may determine the width w of the mesa 130.

FIG. 1F shows an example of a resulting workpiece 20. As is shown, the hard mask laterally protrudes from the mesa 130 at a first lateral end and at a second lateral end of the mesa 130. The first lateral end and the second lateral end are arranged at opposing sides of the mesa 130 along the first lateral direction. The hard mask 123 comprises a conductive layer direct adjacent to a semiconductor layer of the semiconductor layer stack 105. The hard mask 123 is arranged over the semiconductor layer stack and has a width d measured in a first lateral direction.

The mesa 130 has two opposing sidewalls 132. The sidewalls 132 extend in a direction intersecting a horizontal direction. For example, the sidewalls 132 may extend in a vertical direction. According to further embodiments, the extension direction of the sidewalls 132 may be oblique with respect to a vertical direction. For example, the mesas 130 may have a tapered shape, so that a diameter of the mesa 130 on a side facing the growth substrate 100 is larger than on a side remote from the growth substrate 100.

A difference between the width d of the hard mask 123 and the width w of the mesa 130 may be determined by the isotropic etching process. For example, the difference may be larger than 0.2 μm. The difference to be set depends on the diffusion length of the charge carriers and thus the specific semiconductor material employed. The difference may be designed depending on material parameters and the width of the resulting optoelectronic semiconductor device (pixel).

FIG. 1G shows an example of a resulting workpiece 20 after removing the photoresist material 127. For example, a wet cleaning step may be performed in order to clean the resulting surface.

Thereafter, a cover layer 135 is formed over sidewalls 132 of the mesa 130. The cover layer comprises a semiconductor material.

A cover layer 135 may be epitaxially formed, e.g. using an MOCVD (“metal organic chemical vapour deposition”) method. For example, a material of the cover layer 135 may comprise a III-V or a II-VI semiconductor material. For example, a band gap of the cover layer 135 may be larger than the band gap of the active zone 115. For example, the band gap of the material of the cover layer 135 may be larger than the band gap of any layer or quantum well structure constituting the active zone 115.

For example, the cover layer 135 may comprise GaN, AlGaP, InAlP or ZnSSe. The cover layer 135 may be doped or may be semi-insulating. For example, the cover layer may comprise several sublayers of opposite polarity, e.g. n-type, p-type or semi-insulating. The cover layer 135 may fill the space between adjacent mesas.

For example, as is shown in FIG. 1H, the cover layer may comprise a first sublayer 1361 and a second sublayer 1362. The first sublayer 1361 may be of the second conductivity type, e.g. p-type in the present example. Further, the second sublayer 136 may be of the first conductivity type, e.g. n-type in the present example. As a result, a current is blocked around the active portion of the mesa 130. By properly choosing the materials, an ohmic contact from the conductive layer 125 to the semiconductor device is constrained to be only at the second semiconductor layer 120. For example, a band gap of the first sublayer 1361 and/or the second sublayer 1362 may be larger than the band gap of the layers of the active zone 115 and also the top contact layer of the layer stack 120. As is also shown in FIG. 1H, some of the cover material 135 may be formed on top of the hard mask layer 123.

In a next step, for example, this further material of the cover layer 135 may be removed from the hard mask 123, e.g. by polishing. According to further embodiments, this part of the cover material 135 may as well be removed during subsequent processing steps. FIG. 1I shows an example of a resulting workpiece 20.

In a next step, separating grooves 140 are formed so as to separate adjacent optoelectronic semiconductor devices (pixels) 10 from each other. The separating grooves 140 are formed using the hard mask 123 as an etching mask. In particular, an etching step is performed so as to etch the cover layer 135. For example, this may be accomplished using an anisotropic etching method, e.g. dry etching. For example, the separating grooves 140 may be formed to extend to the substrate 100. According to further examples, the separating grooves 140 may be formed so as not to extend to the substrate 100. For example, by forming separating grooves 140 that do not completely separate the single pixels, a pixel array may be formed. In this case, adjacent pixels may be connected by a portion of the first semiconductor layer 110.

FIG. 1J shows an example of a resulting workpiece 20 that may be obtained when the separating grooves 140 are formed so as to extend to the substrate 100. As is shown, a plurality of optoelectronic semiconductor devices 10 are arranged over the substrate 100, the optoelectronic semiconductor devices 10 being separated from each other by the separating grooves 140. After forming the separating grooves 140, a width s of the cover layer 135 may be equal to at least a difference between d and w, the width s being measured in a lateral direction, e.g. the first lateral direction. According to embodiments, the width s of the cover layer 135 may be equal to at least a difference between d and w, the width s being measured in the first lateral direction and further in a second lateral direction, which may be perpendicular to the first lateral direction.

Thereafter, the dielectric layer 124 may be removed from the single optoelectronic semiconductor devices 10, e.g. using an etching process. According to embodiments, a further cleaning step may be performed so as to clean the resulting surface. FIG. 1K shows an example of a resulting structure.

FIG. 1K shows an example of an optoelectronic semiconductor device according to embodiments. An optoelectronic semiconductor device 10 comprises a semiconductor layer stack 105 comprising an active zone 115 for generating or receiving electromagnetic radiation. The semiconductor layer stack 105 is patterned to form a mesa 130 having a width w measured in a first lateral direction, e.g. the x-direction. The mesa 130 may also have a width w measured in a second lateral direction which may be perpendicular to the first lateral direction. For example, the second lateral direction may be the y-direction.

The semiconductor device 10 further comprises a hard mask 123 arranged over the semiconductor layer stack 105 and having a width d, measured in the first lateral direction, with d>w. For example, due to the isotropic etching described with reference to FIG. 1F, the hard mask 123 protrudes from the mesa 130 at a first lateral end and at a second lateral end of the mesa 130. The first lateral end and the second lateral end are arranged at opposing sides of the mesa along the first lateral direction. The hard mask 123 comprises a conductive layer 125 directly adjacent to a semiconductor layer of the semiconductor layer stack 105. The optoelectronic semiconductor device 10 further comprises a cover layer 135 arranged over sidewalls 132 of the mesa 130. The cover layer 135 comprises a semiconductor material.

For example, the hard mask may protrude from the mesa 130 at opposing lateral ends of the mesa, e.g. along the second lateral direction. According to embodiments, the hard mask 123 may protrude at any side of the mesa 130.

As is further shown in FIG. 1K, the conductive layer 125 may at least extend from one side of the mesa to the other side of the mesa 130. For example, the conductive layer 125 may protrude at opposing lateral ends of the mesa, e.g. along the second lateral direction. According to embodiments, the conductive layer 125 may protrude at any side of the mesa 130.

As is further illustrated in FIG. 1K, the cover layer 135 is arranged below the hard mask layer 123. For example, portions of the cover layer 135 are not arranged over horizontal portions of the second semiconductor layer 120. Moreover, a portion of the cover layer 135 may be arranged over a horizontal portion of the first semiconductor layer 110. For example, as is illustrated in FIG. 1K, the cover layer 135 may be flush with respect to the hard mask layer 123. This may be due to the fact that the hard mask has been used for defining the separating grooves 140. The hard mask 123 and the cover layer 135 may encapsulate the active zone 115, the second semiconductor layer 120 and a portion of the first semiconductor layer 110.

The cover layer 135 may be epitaxially grown. For example, atoms or molecules of the cover layer may be bonded to dangling bonds or unpaired bonds at the sidewalls of the mesa 130 in a region of the active zone 115. For example, after etching the mesa, the mesa edges are defective and include dangling bonds which may be recombination centres. As a result, non-radiative combination of carriers may be caused at the mesa edges. Due to the presence of the cover layer, these dangling bonds may be removed or bonded to atoms or molecules of the cover layer 135. Hence, non-radiative recombination may be reduced.

Since, as has been described above, the hard mask 123 that has been used for etching the mesa is also used for defining the separating grooves 140, the alignment accuracy of the separating grooves 140 may be greatly improved. More specifically, a self-aligned formation of the optoelectronic semiconductor devices 10 is enabled.

In particular, when the pixels or optoelectronic semiconductor devices have a small width, e.g. in the order of 1 μm in a lateral direction, a more precise alignment of the separating grooves 140 increases the performance between the manufactured optoelectronic semiconductor devices over a wafer and on a wafer-to-wafer scale. To be more specific, when the optoelectronic semiconductor devices have a small size, the distance between a central portion of the active zone to an edge of the optoelectronic semiconductor devices may determine the degree of non-radiative recombination. Hence, when this distance is set to a uniform value over a wafer or on a wafer-to-wafer scale, a more uniform performance may be achieved. Moreover, additional processing steps for photolithographic defining the position of the separating grooves 140 may be dispensed with.

For example, the conductive layer 125 may comprise a transparent conductive oxide such as ITO. ITO is not attacked during a wet etching process. Further, it is stable at high temperature, e.g. temperatures during growth of the cover layer 135.

FIG. 1K also illustrates an array 15 of optoelectronic semiconductor devices 10. The array 15 comprises a semiconductor layer stack 105 comprising an active zone 115 for generating or receiving electromagnetic radiation, the semiconductor layer stack 105 being patterned to form a plurality of mesas 130 having a width w measured in a first lateral direction. The array 15 further comprises portions of a hard mask 123 arranged over the semiconductor layer stack 105 and having a width d measured in the first lateral direction, with d>w, the hard mask 123 protruding from each of the mesas 130 at a first lateral end and at a second lateral end of each of the mesas 130, the first lateral end and the second lateral end being arranged at opposing sides of the mesas 130 along the first lateral direction. The array further comprises a cover layer 135 arranged over sidewalls of each of the mesas 130, the cover layer 135 comprising a semiconductor material, and a plurality of separating grooves 140 between adjacent optoelectronic semiconductor devices 10, the separating grooves 140 extending between the hard masks 123 of adjacent optoelectronic semiconductor devices 10 and being directly adjacent to the hard masks 123 of the adjacent optoelectronic semiconductor devices 10.

According to further embodiments, the conductive layer 125 may be dispensed with.

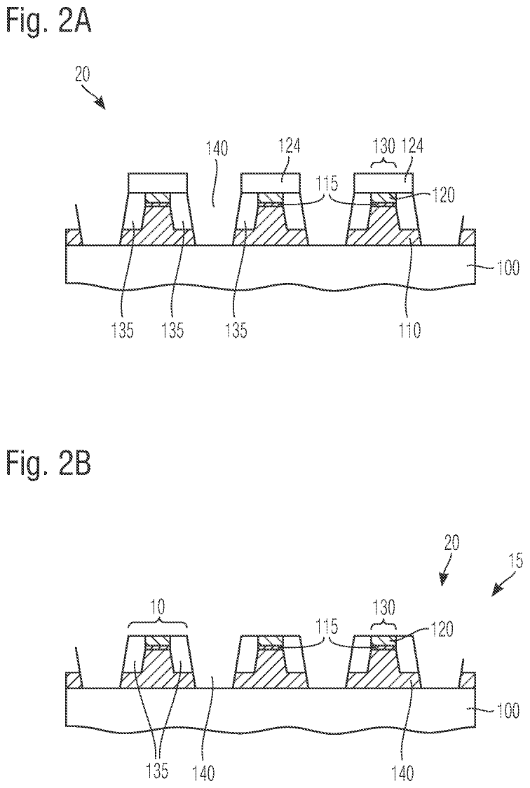

FIG. 2A shows an example of a workpiece 20, wherein the hard mask does not comprise a conductive layer 125 but comprises a dielectric layer 124. The dielectric layer 124 may be in direct contact with the second semiconductor layer 120. In this case, after etching the separating grooves 140, a workpiece 20 as illustrated in FIG. 2A may be obtained. The mesas 130 are covered with the dielectric layer 124. Thereafter, as is shown in FIG. 2B, the dielectric layer 124 may be optionally removed e.g. by polishing or etching. As a result, a surface of the second semiconductor layer 120 may be exposed. According to further modifications, the dielectric layer 124 may comprise two or more sublayers. For example, in this case only the top sublayer may be removed and a sublayer in contact with the first semiconductor layer 120 may be maintained.

FIG. 2B shows further examples of an optoelectronic semiconductor device 10 or an array 15 of optoelectronic semiconductor devices.

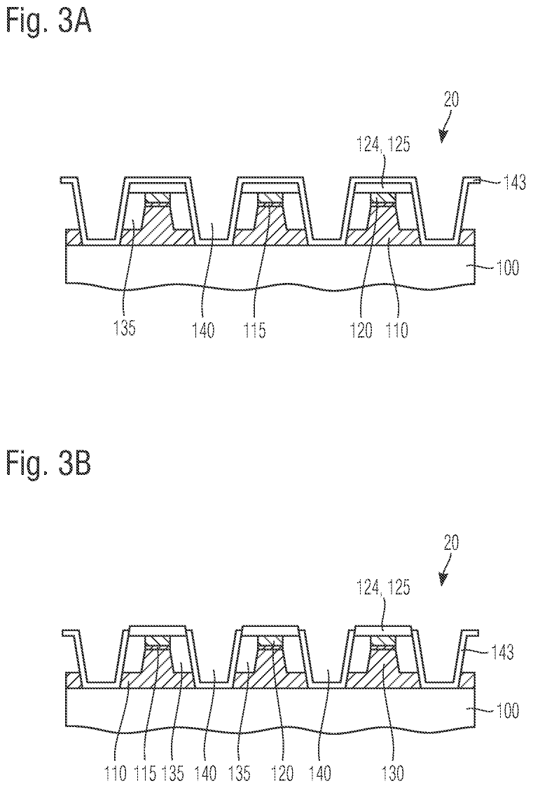

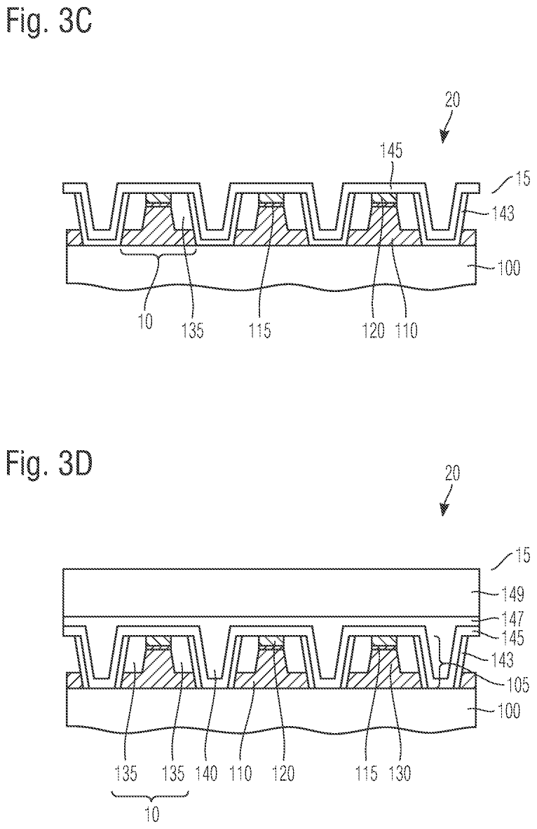

Starting from any of FIG. 2A or 1J or 1K, the processing illustrated in FIGS. 3A to 3B may be performed. For example, a passivation layer 143 may be deposited over the workpiece 20. For example, a passivation layer 143 may be deposited so as to cover a surface of the dielectric layer 124 or the conductive layer 125. Further, the passivation layer 143 covers the cover layer 135, i.e. the sidewalls 132 of the mesa 130. FIG. 3A shows an example of a resulting workpiece 20.

Thereafter, a polishing step may be performed so as to polish horizontal portions of the passivation layer 143 arranged over the mesas 130. As a result, a surface of the dielectric layer 124 or the conductive layer 125 is exposed.

As is illustrated in FIG. 3B due to the polishing, a surface of the dielectric layer or the conductive layer 125 may be exposed without attacking the passivation layer 143 on the sidewalls. The sidewalls of the separating grooves 140 are covered with the passivation layer 143. For further processing, for example, the dielectric layer 124 may be removed from the surface of the second semiconductor layer 120. After performing this processing step, the surface of the second semiconductor layer 120 is exposed or covered with conductive layer 125. Thereafter, a contact layer 145 may be formed over the surface of the workpiece 20. For example, the contact layer 145 may comprise a metal or a transparent conductive oxide such as ITO.

FIG. 3C shows an example of a resulting workpiece 20. The contact layer 145 is formed to be in direct contact with the second semiconductor layer. The passivation layer 143 separates the sidewalls of the mesa 130 from the contact layer 145.

Thereafter, as is illustrated in FIG. 3D, a bonding metal 147 may be formed over the surface of the workpiece, followed by a carrier 149. For example, the bonding metal 147 may comprise a suitable metal for reflecting light back through the semiconductor and for bonding the workpiece 20 to the carrier 149. FIG. 3D shows a cross-sectional view of a plurality of semiconductor devices 10 or an array 15 of semiconductor devices 10 according to further embodiments.

Thereafter, for example, the substrate 100 may be removed from the workpiece, allowing the placement of a second contact to the device. This second contact can also be obtained through the grooves so that both contacts are formed on the same side. The light emission may be through the side that is remote from the bonded carrier. Other processing steps such as to make the array transfer-printable onto an electronic driver (for example, CMOS) wafer or directly bonded onto the driver wafer are also possible.

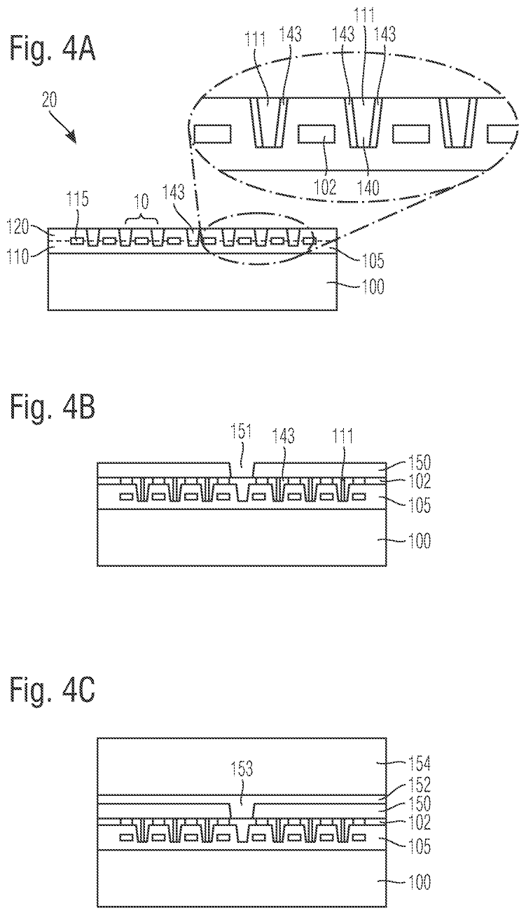

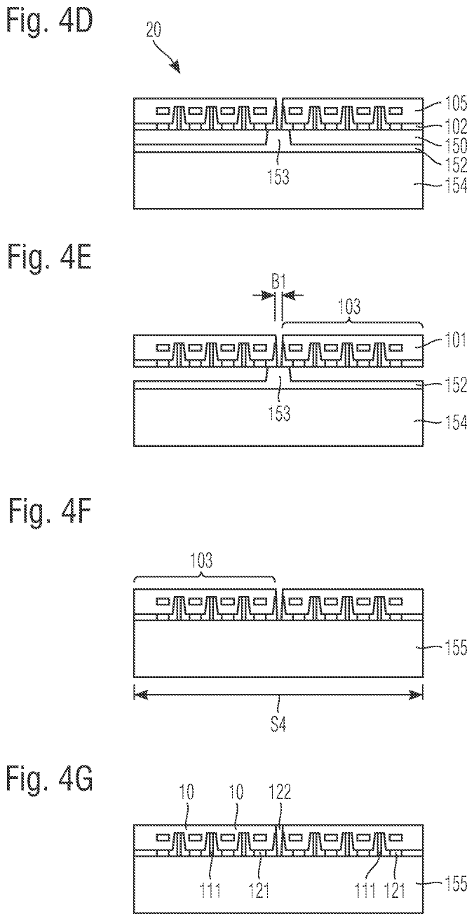

For example, starting from a workpiece similar to a workpiece explained with reference to FIG. 3B, the processing illustrated in FIGS. 4A to 4G may be performed. The workpiece 20 shown in FIG. 4A includes separation grooves 140 which do not extend to the substrate 100. Adjacent optoelectronic semiconductor devices 10 are electrically connected by a portion of the first semiconductor layer 110. The workpiece 20 is similar to the workpiece 20 shown in FIG. 3B, including a dielectric layer 124 over the second semiconductor layer 120. Horizontal portions of the passivation layer 143 are removed to expose a portion of a surface of the first semiconductor layer. Thereafter, a conductive material may be filled in the separating grooves 140. As a result, first contact elements 111 are formed in the separating grooves 140. A planarizing step may be performed so as to remove the conductive material from the planar surface of the workpiece 120 (FIG. 4A). Thereafter, a release layer 150 may be formed over the resulting surface. An opening 151 is formed in the release layer 150 (FIG. 4B).

Then, as is illustrated in FIG. 4C, an intermediate carrier 154 may be attached to the release layer 150 via a bonding layer 152. The bonding layer 152 fills the opening to form a post 153. Thereafter, the substrate 100 is removed from the resulting workpiece.

FIG. 4D shows an example of a resulting workpiece. Then, the release layer 150 is removed so that groups 103 of optoelectronic semiconductor devices are attached to the intermediate carrier 154 via the post 153 (FIG. 4E). As is shown in FIG. 4F, the groups 103 are then transferred to a target carrier 155. For example, the target carrier 155 may have a lateral dimension S4 which is larger than the lateral dimension Si of the substrate 100.

Thereafter, second contact pads 122 may be formed so as to be connected to the second contact elements 121, as is shown in FIG. 4G.

Thereafter, for example, a wiring pattern may be provided over the target carrier 155 so as to electrically connect the second contact elements 121 with the second contact pads 122 and to address the first contact elements 111. Further wiring schemes may be applied so as to electrically contact the first and the second semiconductor layers of each of the optoelectronic semiconductor devices. For example, the first and the second contact elements 111, 121 may be formed from opposite sides of the workpiece 20.

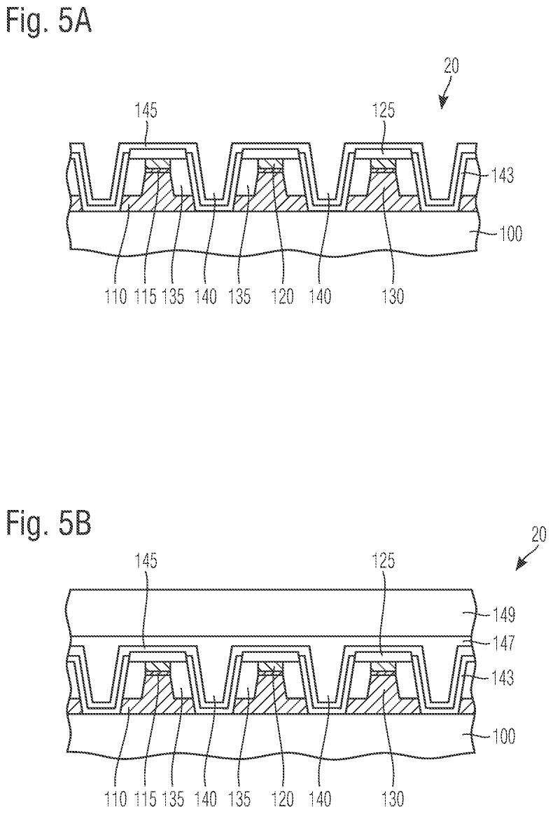

FIG. 5A shows a cross-sectional view of a workpiece 20 that may be obtained when the described processing is performed using the workpiece illustrated in FIG. 3B in which the conductive layer 125 is present over the surface of the mesas. As is illustrated in FIG. 5A, the contact layer 145 is formed to be in direct contact with the conductive layer 125, e.g. the ITO layer which was part of the hard mask layer 123. The passivation layer 143 separates the sidewalls of the mesa 130 from the contact layer 145.

Thereafter, as is illustrated in FIG. 5B, a bonding metal 147 may be formed over the surface of the workpiece illustrated in FIG. 5A, followed by a carrier 149. For example, the bonding metal 147 may comprise suitable metal for reflecting light back through the semiconductor layers and for bonding the workpiece 20 to the carrier 149. FIG. 5B shows a cross-sectional view of a plurality of semiconductor devices 10 or an array 15 of semiconductor devices 10 according to further embodiments.

Thereafter, for example, the substrate 100 may be removed from the workpiece, allowing the placement of second contact elements to the device. This second contact element may also be obtained through the grooves so that both contacts are formed on the same side. For example, forming the first and second contact elements may accomplish in the manner as has been explained with reference to FIGS. 4A to 4G. According to further embodiments, the first and the second contact elements 111, 121 may be formed from opposite sides of the workpiece 20. The light emission will be affected through the side that is remote from the bonded carrier. Other processing steps such as to make the array transfer-printable onto an electronic driver (for example, CMOS) wafer or directly bonded onto the driver wafer are also possible.

The described contacting of the semiconductor layer 120 or the conductive layer 125 may also be achieved using lithographic methods and etching processes. For example, instead of polishing the passivation layer 143, the passivation layer 143 on top of the pixel may be etched to expose the semiconductor layer 120 or the conductive layer 125.

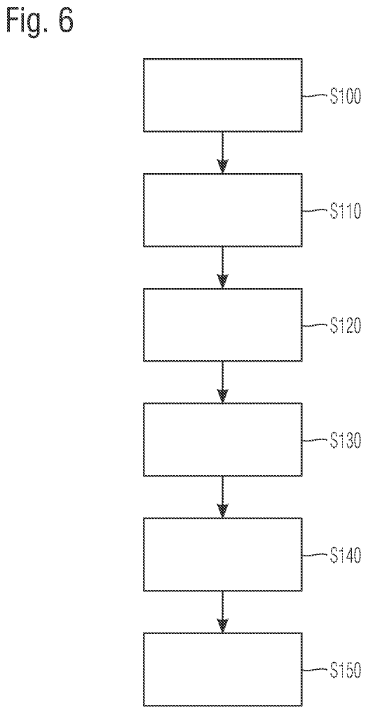

FIG. 6 summarizes a method according to embodiments. As is shown, a method of manufacturing an optoelectronic semiconductor device comprises forming (S100) a semiconductor layer stack comprising an active zone for generating electromagnetic radiation, forming (S110) a hard mask layer over the semiconductor layer stack, patterning (S120) the hard mask layer to form a hard mask having a width d measured in the first lateral direction, and patterning (S130) the semiconductor layer stack to form a mesa having a width w measured in a first lateral direction with d>w. The hard mask layer protrudes from the mesa at a first lateral end and at a second lateral end of the mesa, the first lateral end and the second lateral end being arranged at opposing sides of the mesa along the first lateral direction. The method further comprises forming (S140) a cover layer over sidewalls of the mesa, the cover layer comprising a semiconductor material, and etching (S150) the semiconductor material of the cover layer using the hard mask as an etching mask to form a separating groove.

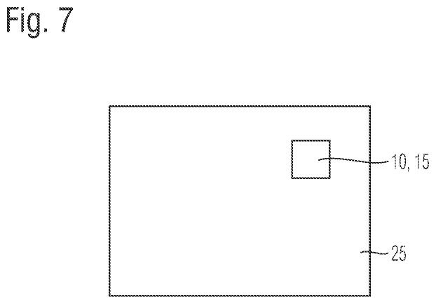

FIG. 7 shows an optoelectronic apparatus 25 according to embodiments. The optoelectronic apparatus 25 comprises the optoelectronic semiconductor device 10 or the array 15 of optoelectronic semiconductor devices 10 as described above. For example, the optoelectronic apparatus may be a display apparatus for Augmented or Virtual Reality applications. According to further embodiments, the optoelectronic apparatus 25 may be a high speed photodetector.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

1-20. (canceled)

21. A method for manufacturing an optoelectronic semiconductor device, the method comprising:
forming a semiconductor layer stack comprising an active zone for generating or receiving electromagnetic radiation;
thereafter, forming a hard mask layer over the semiconductor layer stack;
thereafter, patterning the hard mask layer to form a hard mask having a width d measured in a first lateral direction;
thereafter, patterning the semiconductor layer stack to form a mesa having a width w measured in the first lateral direction with d>w, wherein the hard mask protrudes from the mesa at a first lateral end and at a second lateral end of the mesa, and wherein the first lateral end and the second lateral end are arranged at opposing sides of the mesa along the first lateral direction;
thereafter, forming a cover layer over sidewalls of the mesa, the cover layer comprising a semiconductor material; and
thereafter, etching the semiconductor material of the cover layer using the hard mask as an etching mask to form a separating groove.

22. The method according to claim 21, wherein patterning the semiconductor layer stack comprises anisotropic etching followed by isotropic etching.

23. The method according to claim 21, wherein the semiconductor layer stack comprises a first semiconductor layer of a first conductivity type, a second semiconductor layer of a second conductivity type and the active zone arranged between the first semiconductor layer and the second semiconductor layer, wherein the second semiconductor layer is formed to be directly adjacent to the hard mask layer.

24. The method according to claim 23, wherein forming the hard mask layer comprises forming a conductive layer directly adjacent to the second semiconductor layer of the semiconductor layer stack.

25. The method according to claim 23, wherein forming the hard mask layer comprises forming a dielectric layer directly adjacent to the second semiconductor layer of the semiconductor layer stack.

26. The method according to claim 25, further comprising removing the dielectric layer after forming the separating groove.

27. The method according to claim 21, further comprising
forming a passivation layer after forming the separating groove;
removing horizontal portions of the passivation layer to expose a surface of the mesas; and
forming a conductive material to cover the surface of the mesas.

28. The method according to claim 21, wherein, due to forming the separating grooves, a plurality of semiconductor devices are obtained.

29. The method according to claim 21, wherein a portion of the semiconductor layer stack is maintained when forming the separating grooves.

30. An optoelectronic semiconductor device comprising:
a semiconductor layer stack comprising an active zone configured to generate or receive electromagnetic radiation, the semiconductor layer stack being patterned to form a mesa having a width w measured in a first lateral direction;
a hard mask arranged over the semiconductor layer stack and having a width d measured in the first lateral direction, with d>w, wherein the hard mask protrudes from the mesa at a first lateral end and at a second lateral end of the mesa, wherein the first lateral end and the second lateral end are arranged at opposing sides of the mesa along the first lateral direction, and wherein the hard mask comprises a conductive layer directly adjacent to a semiconductor layer of the semiconductor layer stack; and
a cover layer arranged over sidewalls of the mesa, the cover layer comprising a semiconductor material.

31. The optoelectronic semiconductor device according to claim 30, wherein the hard mask further comprises a dielectric layer.

32. The optoelectronic semiconductor device according to claim 30, wherein a width s of the cover layer is equal to at least a difference between d and w, the width s being measured in the first lateral direction.

33. The optoelectronic semiconductor device according to claim 30, wherein a band gap of a material of the cover layer is larger than a band gap of the active zone.

34. The optoelectronic semiconductor device according to claim 30, wherein the semiconductor layer stack comprises a first semiconductor layer of a first conductivity type, a second semiconductor layer of a second conductivity type and the active zone arranged between the first semiconductor layer and the second semiconductor layer, the second semiconductor layer being directly adjacent to the conductive layer.

35. The optoelectronic semiconductor device according to claim 34, wherein the cover layer comprises a first sublayer of the second conductivity type and a second sublayer of the first conductivity type, the first sublayer being directly adjacent to the sidewalls of the mesa.

36. The optoelectronic semiconductor device according to claim 35, wherein a band gap of the first sublayer is larger than a band gap of the active zone.

37. The optoelectronic semiconductor device according to claim 35, wherein a band gap of the second sublayer is larger than the band gap of the active zone.

38. An array of optoelectronic semiconductor devices, each optoelectronic semiconductor device being the optoelectronic semiconductor device according to claim 30, wherein adjacent optoelectronic semiconductor devices are separated from each other by a separating groove in the cover layer, and wherein the separating groove extends between the hard masks of the adjacent optoelectronic semiconductor devices.

39. An array of optoelectronic semiconductor devices comprising:
a semiconductor layer stack comprising an active zone configured to generate or receive electromagnetic radiation, the semiconductor layer stack being patterned to form a plurality of mesas having a width w measured in a first lateral direction;
portions of a hard mask arranged over the semiconductor layer stack and having a width d measured in the first lateral direction, with d>w, wherein the hard mask protrudes from each of the mesas at a first lateral end and at a second lateral end of each of the mesas, and wherein the first lateral end and the second lateral end are arranged at opposing sides of the mesas along the first lateral direction;
a cover layer arranged over sidewalls of each of the mesas, the cover layer comprising a semiconductor material; and
a plurality of separating grooves between adjacent optoelectronic semiconductor devices, wherein the separating grooves extend between the portions of the hard mask of adjacent optoelectronic semiconductor devices and are directly adjacent to the portions of the hard mask of the adjacent optoelectronic semiconductor devices.
